(19) United States
(12) Patent Application Publication
(10) Pub. No.: US 2012/0256692 A1
(43) Pub. Date: Oct. 11, 2012

(54) OSCILLATOR

(75) Inventors: Aritsugu YAJIMA, Matsumoto (JP); Shogo INABA, Shiojiri (JP); Ryuji KIHARA, Matsumoto (JP)

(73) Assignee: SEIKO EPSON CORPORATION, Tokyo (JP)

(21) Appl. No.: 13/439,362

(22) Filed: Apr. 4, 2012

(30) Foreign Application Priority Data
Apr. 5, 2011 (JP) 2011-083353

(51) Int. Cl. H03L 7/083

(52) U.S. Cl. 331/25

(57) ABSTRACT

An oscillator includes: a substrate; a reference oscillation circuit including a first MEMS oscillator disposed above the substrate, the reference oscillation circuit outputting a first oscillation signal; at least one voltage-controlled oscillation circuit including a second MEMS oscillator disposed above the substrate, the oscillation frequency of the at least one voltage-controlled oscillation circuit being controlled based on a control signal, the at least one voltage-controlled oscillation circuit outputting a second oscillation signal; a frequency division circuit dividing the frequency of the second oscillation signal and outputting a frequency division signal; and a phase-comparison circuit outputting the control signal based on a phase difference between the frequency division signal and the first oscillation signal, wherein the first MEMS oscillator and the second MEMS oscillator each have a first electrode and a second electrode, the second electrode has a movable part disposed so as to face the first electrode.

### BACKGROUND

1. Technical Field

The present invention relates to oscillators.

2. Related Art

The features of a phase-locked loop (PLL) are that the PLL can obtain an output signal having a high degree of frequency accuracy and vary the frequency of the output signal. An oscillator having the PLL is used in a wide range of fields such as the communications field (see, for example, JP-A-2010-278751).

Specifically, the oscillator having the PLL compares the phase of a reference signal which is a reference frequency with the phase of a feedback signal which is output from a frequency division circuit and inputs a signal according to the phase difference to a voltage-controlled oscillator, whereby the oscillator can output an output signal with a frequency which is an integral multiple of the frequency of the reference signal.

Such an oscillator having the PLL generally obtains a reference signal which is a reference frequency from an oscillation circuit using a quartz oscillator. This is because the use of the quartz oscillator makes it possible to obtain a stable frequency having a high degree of accuracy.

Here, in general, it is difficult to mount a quartz oscillator on a semiconductor substrate. Therefore, in the oscillator having the PLL, the quartz oscillator cannot be mounted on the semiconductor substrate, for example, and is externally attached. This undesirably increases the size of a device.

### SUMMARY

An advantage of some aspects of the invention is to provide an oscillator that is an oscillator having a PLL and can achieve miniaturization.

An aspect of the invention is directed to an oscillator including: a substrate; a reference oscillation circuit including a first MEMS oscillator disposed above the substrate, the reference oscillation circuit outputting a first oscillation signal; at least one voltage-controlled oscillation circuit including a second MEMS oscillator disposed above the substrate, the oscillation frequency of the at least one voltage-controlled oscillation circuit being controlled based on a control signal, the at least one voltage-controlled oscillation circuit outputting a second oscillation signal; a frequency division circuit dividing the frequency of the second oscillation signal and outputting a frequency division signal; and a phase-comparison circuit outputting the control signal based on a phase difference between the frequency division signal and the first oscillation signal, wherein the first MEMS oscillator and the second MEMS oscillator each have a first electrode and a second electrode, the second electrode has a movable part disposed so as to face the first electrode, and the area of the movable part of the first MEMS oscillator is greater than the area of the movable part of the second MEMS oscillator in a plan view of the substrate.

Such an oscillator can be provided with the reference oscillation circuit including the first MEMS oscillator. This makes it possible to dispose the oscillator forming the reference oscillation circuit on the substrate without externally attaching the oscillator. As a result, it is possible to achieve miniaturization of a device.

Furthermore, such an oscillator can be provided with the voltage-controlled oscillation circuit including the second MEMS oscillator. An oscillation circuit using a MEMS oscillator can make the area thereof in the substrate smaller as compared to, for example, an LC oscillation circuit which is generally used in a voltage-controlled oscillation circuit. This makes it possible to achieve miniaturization of the device.

In the description of the invention, when the term “above” is used in a sentence such as “above a specific object (hereinafter referred to as “A”), another specific object (hereinafter referred to as “B”) is formed”, the term “above” covers not only cases where B is formed directly on A but also cases where B is formed on A with another object sandwiched between B and A.

The oscillator according to the aspect of the invention may further include a support substrate disposed above the substrate, one of the first MEMS oscillator and the second MEMS oscillator may be disposed between the substrate and the support substrate, and the other of the first MEMS oscillator and the second MEMS oscillator may be disposed above the support substrate.

With such an oscillator, it is possible to reduce the size of the device in a plan view.

In the oscillator according to the aspect of the invention, a cavity space surrounding the first MEMS oscillator may have a region overlapping with a cavity space surrounding the second MEMS oscillator in a plan view of the substrate.

With such an oscillator, it is possible to reduce the size of the device in a plan view.

In the oscillator according to the aspect of the invention, the reference oscillation circuit, the at least one voltage-controlled oscillation circuit, the frequency division circuit, and the phase-comparison circuit may be disposed above the substrate.

With such an oscillator, it is possible to achieve miniaturization of the device. Furthermore, for example, the oscillator can be formed as one chip.

In the oscillator according to the aspect of the invention, the at least one voltage-controlled oscillation circuit may include a plurality of voltage-controlled oscillation circuits, the oscillation frequencies of the plurality of voltage-controlled oscillation circuits may be different from one another, and the oscillator may further include a selection circuit selecting one of the plurality of voltage-controlled oscillation circuits.

With such an oscillator, it is possible to increase the variable width of the frequency of the output signal output from the oscillator.

In the oscillator according to the aspect of the invention, the plurality of voltage-controlled oscillation circuits may have second MEMS oscillators, the resonance frequencies of the second MEMS oscillators being different from one another.

With such an oscillator, it is possible to increase the variable width of the frequency of the output signal output from the oscillator.

Another aspect of the invention is directed to an oscillator including: a substrate having a first surface and a second surface on a side opposite to the first surface; a reference oscillation circuit including a first MEMS oscillator disposed on a side where the first surface is located, the reference oscillation circuit outputting a first oscillation signal; a voltage-controlled oscillation circuit including a second MEMS oscillator disposed on a side where the second surface is located, the oscillation frequency of the voltage-controlled oscillation circuit being controlled based on a control signal, the voltage-controlled oscillation circuit outputting a second oscillation signal; a frequency division circuit dividing the frequency of the second oscillation signal and outputting a frequency division signal; and a phase-comparison circuit outputting the control signal based on a phase difference between the frequency division signal and the first oscillation signal, wherein the first MEMS oscillator and the second MEMS oscillator each have a first electrode and a second electrode, the second electrode has a movable part disposed so as to face the first electrode, and the area of the movable part of the first MEMS oscillator is greater than the area of the movable part of the second MEMS oscillator in a plan view of the substrate.

Such an oscillator can be provided with the reference oscillation circuit including the first MEMS oscillator. This makes it possible to dispose the oscillator forming the reference oscillation circuit on the substrate without externally attaching the oscillator. As a result, it is possible to achieve miniaturization of the device.

Furthermore, such an oscillator can be provided with the voltage-controlled oscillation circuit including the second MEMS oscillator. An oscillation circuit using a MEMS oscillator can make the area thereof in the substrate smaller as compared to, for example, an LC oscillation circuit which is generally used in a voltage-controlled oscillation circuit. This makes it possible to achieve miniaturization of the device.

### BRIEF DESCRIPTION OF THE DRAWINGS

The invention will be described with reference to the accompanying drawings, wherein like numbers reference like elements.

FIG. 1 is a block diagram showing the configuration of an oscillator according to a first embodiment.

FIG. 2 is a circuit diagram showing a reference oscillation circuit of the oscillator according to the first embodiment.

FIG. 3 is a circuit diagram showing a modified example of the reference oscillation circuit of the oscillator according to the first embodiment.

FIG. 4 is a circuit diagram showing a voltage-controlled oscillation circuit of the oscillator according to the first embodiment.

FIG. 5 is a sectional view schematically showing the oscillator according to the first embodiment.

FIG. 6 is a plan view schematically showing a first MEMS oscillator of the oscillator according to the first embodiment.

FIG. 7 is a sectional view schematically showing the first MEMS oscillator of the oscillator according to the first embodiment.

FIG. 8 is a plan view schematically showing a second MEMS oscillator of the oscillator according to the first embodiment.

FIG. 9 is a sectional view schematically showing the second MEMS oscillator of the oscillator according to the first embodiment.

FIG. 10 is a sectional view schematically showing a production process of the oscillator according to the first embodiment.

FIG. 11 is a sectional view schematically showing a production process of the oscillator according to the first embodiment.

FIG. 12 is a sectional view schematically showing a production process of the oscillator according to the first embodiment.

FIG. 13 is a sectional view schematically showing a production process of the oscillator according to the first embodiment.

FIG. 14 is a sectional view schematically showing a production process of the oscillator according to the first embodiment.

FIG. 15 is a sectional view schematically showing a production process of the oscillator according to the first embodiment.

FIG. 16 is a sectional view schematically showing an oscillator according to a first modified example of the first embodiment.

FIG. 17 is a sectional view schematically showing an oscillator according to a second modified example of the first embodiment.

FIG. 18 is a sectional view schematically showing an oscillator according to a third modified example of the first embodiment.

FIG. 19 is a block diagram showing the configuration of an oscillator according to a second embodiment.

FIG. 20 is a circuit diagram showing a voltage-controlled oscillation circuit of the oscillator according to the second embodiment.

FIG. 21 is a sectional view schematically showing the oscillator according to the second embodiment.

### DESCRIPTION OF EXEMPLARY EMBODIMENTS

Hereinafter, preferred embodiments of the invention will be described in detail by using the drawings. It should be understood that the embodiments described below are not meant to limit unduly the scope of the invention claimed in the appended claims in any way, and all the configurations described below are not always necessary requirements of the invention.

### 1. First Embodiment

### 1.1 Configuration of an Oscillator According to a First Embodiment

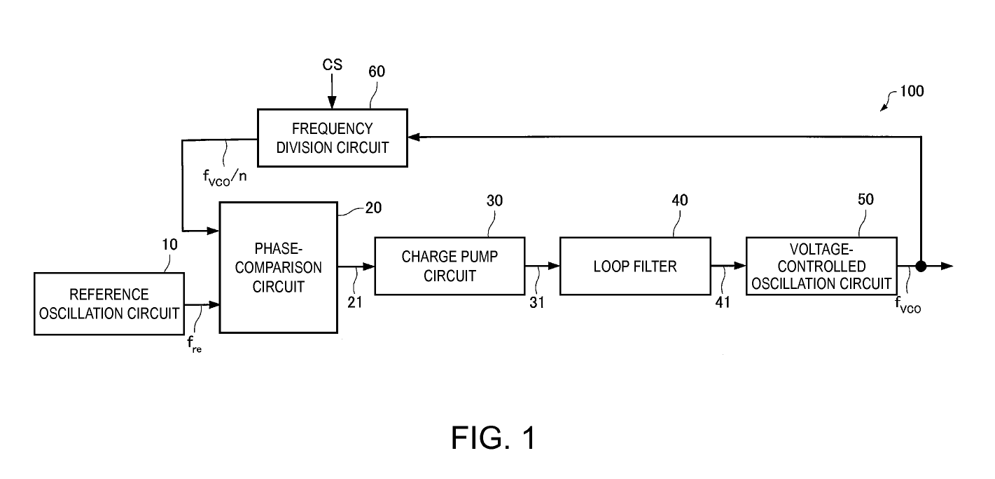

First, an oscillator according to a first embodiment will be described with reference to the drawings. FIG. 1 is a block diagram showing the configuration of an oscillator 100 according to this embodiment.

The oscillator 100 includes a substrate, a reference oscillation circuit 10 including a first MEMS oscillator disposed above the substrate, a phase-comparison circuit 20, a charge pump circuit 30, a loop filter 40, a voltage-controlled oscillation circuit 50 including a second MEMS oscillator disposed above the substrate, and a frequency division circuit 60. The reference oscillation circuit 10, the phase-comparison circuit 20, the charge pump circuit 30, the loop filter 40, the voltage-controlled oscillation circuit 50 and the frequency division circuit 60 form a phase-locked loop (PLL).

The reference oscillation circuit 10 outputs a reference signal (a first oscillation signal) fᵣₑ. FIG. 2 is a circuit diagram showing the reference oscillation circuit 10. The reference oscillation circuit 10 has, for example, a first MEMS oscillator 12 and an inverting amplifier circuit 14.

The first MEMS oscillator 12 is, for example, an electrostatic MEMS oscillator. The first MEMS oscillator 12 has a Q value which is higher than that of the second MEMS oscillator used in the voltage-controlled oscillation circuit 50. Therefore, the reference oscillation circuit 10 using the first MEMS oscillator 12 can output the signal fᵣₑ having a higher degree of frequency accuracy as compared to the voltage-controlled oscillation circuit 50. The first MEMS oscillator 12 has a first terminal 12a and a second terminal 12b. The first terminal 12a of the first MEMS oscillator 12 at least AC-connects to an input terminal 14a of the inverting amplifier circuit 14. The second terminal 12b of the first MEMS oscillator 12 at least AC-connects to an output terminal 14b of the inverting amplifier circuit 14. Incidentally, a configuration example of the first MEMS oscillator 12 will be described later.

The inverting amplifier circuit 14 may be formed by combining a plurality of inverters (inverting circuits) and amplifier circuits so that desired oscillation conditions are met. In an example shown in FIG. 2, the inverting amplifier circuit 14 is formed of an inverter 14-1, an inverter 14-2, and an inverter 14-3 which are connected, in this order, in series from the input terminal 14a to the output terminal 14b.

The reference oscillation circuit 10 may include a feedback resistance for the inverting amplifier circuit 14. In the example shown in FIG. 2, an input terminal and an output terminal of the inverter 14-1 are connected via a resistance 16, and an input terminal and an output terminal of the inverter 14-2 are connected via a resistance 17, and an input terminal and an output terminal of the inverter 14-3 are connected via a resistance 18.

The reference oscillation circuit 10 includes a first capacitor 19a connected between the input terminal 14a of the inverting amplifier circuit 14 and a reference potential (a ground potential) and a second capacitor 19b connected between the output terminal 14b of the inverting amplifier circuit 14 and the reference potential (the ground potential). As a result, the reference oscillation circuit 10 can be formed as an oscillation circuit in which the first MEMS oscillator 12 and the capacitors 19a and 19b form a resonance circuit. The reference oscillation circuit 10 outputs an oscillation signal obtained by the oscillation circuit as a reference signal fᵣₑ. As shown in FIG. 1, the reference signal fᵣₑ is input to the phase-comparison circuit 20.

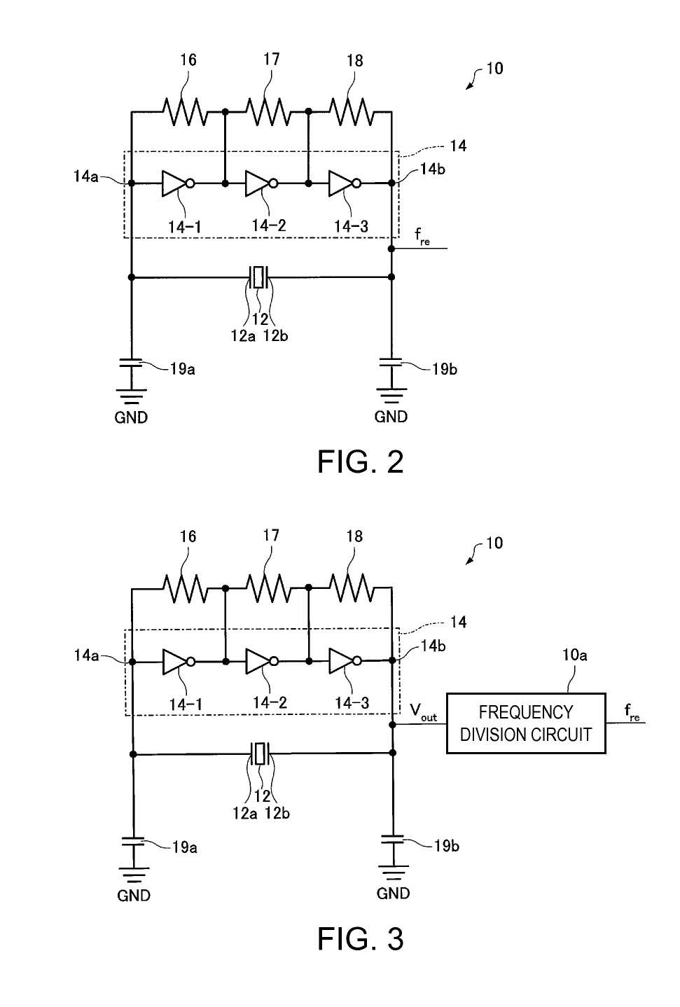

Incidentally, as shown in FIG. 3, the reference oscillation circuit 10 may further include a frequency division circuit 10a. The frequency division circuit 10a divides the frequency of an output signal Vₒᵤₜ of the oscillation circuit and outputs a reference signal fᵣₑ. As a result, the oscillator 100 can obtain an output signal with a frequency which is lower than the frequency of the output signal Vₒᵤₜ, for example.

As shown in FIG. 1, the phase-comparison circuit 20 compares the phase of the reference signal fᵣₑ with the phase of a feedback signal (a frequency division signal) f_{VCO}/n (n is a positive integer) which is an output signal of the frequency division circuit 60 to obtain a phase difference between these signals, and outputs a control signal 21 based on the phase difference thus obtained. The phase-comparison circuit 20 has two input terminals. To one input terminal, the reference signal fᵣₑ is input, and, to the other input terminal, the feedback signal f_{VCO}/n is input. The control signal 21 is input to the charge pump circuit 30.

The charge pump circuit 30 includes a capacitor. In the capacitor, charges are accumulated depending on the control signal 21. The charge pump circuit 30 outputs a voltage defined by the charges accumulated in the capacitor as a control voltage 31. That is, the charge pump circuit 30 converts the control signal 21 into the control voltage 31. The control voltage 31 is input to the loop filter 40.

The loop filter 40 removes a high-frequency component from the control voltage 31 and outputs a control voltage 41. The control voltage 41 is input to the voltage-controlled oscillation circuit 50.

The voltage-controlled oscillation circuit 50 outputs an oscillation signal (a second oscillation signal) f_{VCO} as a result of the oscillation frequency being controlled based on the control signal 21. In the example shown in the drawing, the control signal 21 output from the phase-comparison circuit 20 is converted into the control voltage 31 by the charge pump circuit 30, a high-frequency component of the control voltage 31 is removed by the loop filter 40 to obtain the control voltage 41, and the control voltage 41 is input to the voltage-controlled oscillation circuit 50. Then, in the voltage-controlled oscillation circuit 50, the oscillation frequency is controlled based on the control voltage 41. Based on the control voltage 41 (the control signal 21), the voltage-controlled oscillation circuit 50 varies the oscillation frequency in such a way that the phase of the feedback signal f_{VCO}/n coincides with the phase of the reference signal fᵣₑ. The voltage-controlled oscillation circuit 50 outputs the oscillation signal f_{VCO} to the outside. That is, the oscillation signal f_{VCO} becomes an output signal of the oscillator 100. Moreover, the oscillation signal f_{VCO} of the voltage-controlled oscillation circuit 50 is fed back to the phase-comparison circuit 20 via the frequency division circuit 60.

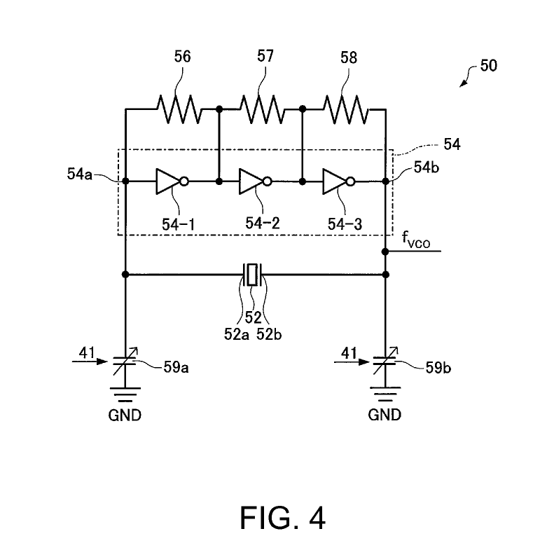

FIG. 4 is a circuit diagram showing the voltage-controlled oscillation circuit 50. The voltage-controlled oscillation circuit 50 has, for example, a second MEMS oscillator 52, an inverting amplifier circuit 54, a first variable capacitor 59a, and a second variable capacitor 59b.

The second MEMS oscillator 52 is, for example, an electrostatic MEMS oscillator. The second MEMS oscillator 52 has a Q value which is lower than that of the first MEMS oscillator 12 used in the reference oscillation circuit 10, for example. Therefore, the voltage-controlled oscillation circuit 50 using the second MEMS oscillator 52 can increase the variable width of the oscillation frequency as compared to the reference oscillation circuit 10. The second MEMS oscillator 52 has a first terminal 52a and a second terminal 52b. The first terminal 52a of the second MEMS oscillator 52 at least AC-connects to an input terminal 54a of the inverting amplifier circuit 54. The second terminal 52b of the second MEMS oscillator 52 at least AC-connects to an output terminal 54b of the inverting amplifier circuit 54. Incidentally, a configuration example of the second MEMS oscillator 52 will be described later.

The inverting amplifier circuit 54 may be formed by combining a plurality of inverters (inverting circuits) and amplifier circuits so that desired oscillation conditions are met. In an example shown in FIG. 4, the inverting amplifier circuit 54 is formed of an inverter 54-1, an inverter 54-2, and an inverter 54-3 which are connected, in this order, in series from the input terminal 54a to the output terminal 54b.

The voltage-controlled oscillation circuit 50 may include a feedback resistance for the inverting amplifier circuit 54. In the example shown in FIG. 4, an input terminal and an output terminal of the inverter 54-1 are connected via a resistance 56, an input terminal and an output terminal of the inverter 54-2 are connected via a resistance 57, and an input terminal and an output terminal of the inverter 54-3 are connected via a resistance 58.

The first variable capacitor 59a is connected between the input terminal 54a of the inverting amplifier circuit 54 and a reference potential (a ground potential). The second variable capacitor 59b is connected between the output terminal 54b of the inverting amplifier circuit 54 and the reference potential (the ground potential).

The control voltage 41 is applied to the variable capacitors 59a and 59b. When the control voltage 41 is applied to the variable capacitors 59a and 59b, the capacitance of the variable capacitors 59a and 59b varies depending on the control voltage 41, and the oscillation frequency of the voltage-controlled oscillation circuit 50 varies. In this way, the voltage-controlled oscillation circuit 50 can vary the oscillation frequency in such a way that the phase of the feedback signal f_{VCO}/n and the phase of the reference signal fᵣₑ coincide with each other.

As shown in FIG. 1, the frequency division circuit 60 divides the frequency of the oscillation signal f_{VCO} by a desired frequency division ratio n (n is a positive integer) and outputs a feedback signal (a frequency division signal) f_{VCO}/n. The frequency division ratio n may be variable. This makes it possible to control the frequency of the output signal of the oscillator 100. For example, the frequency division circuit 60 may receive a control signal CS, and the frequency division ratio n may be controlled based on the control signal CS. Incidentally, the frequency division ratio n of the frequency division circuit 60 may be fixed. The feedback signal f_{VCO}/n is input to the phase-comparison circuit 20.

In the oscillator 100, the reference oscillation circuit 10 outputs the reference signal fᵣₑ, the frequency division circuit 60 outputs the feedback signal f_{VCO}/n, the phase-comparison circuit 20 outputs the control signal 21 based on the phase difference between the reference signal fᵣₑ and the feedback signal f_{VCO}/n, and the voltage-controlled oscillation circuit 50 outputs the oscillation signal f_{VCO} as a result of the oscillation frequency being controlled based on the control signal 21. As a result, the oscillator 100 can output the signal f_{VCO} at a frequency which is n times the frequency of the reference signal fᵣₑ.

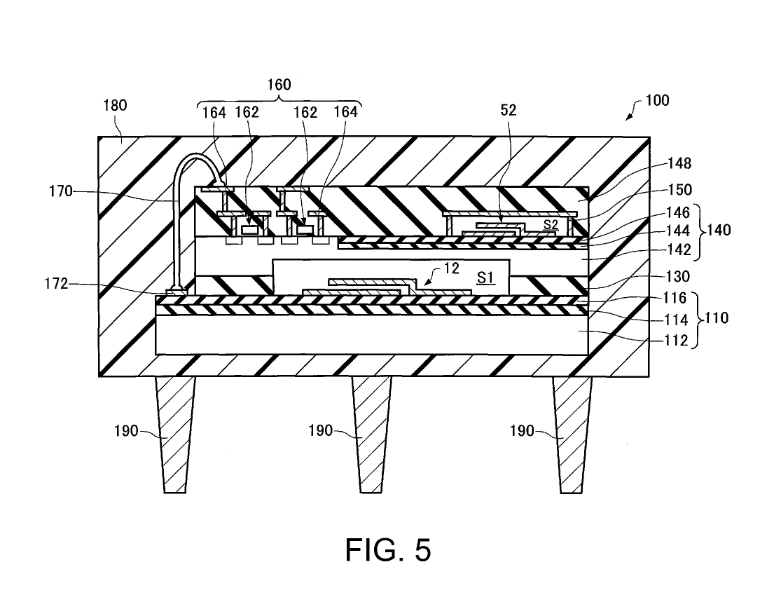

FIG. 5 is a sectional view schematically showing the oscillator 100.

In the oscillator 100, as shown in FIG. 5, the first MEMS oscillator 12 is disposed above a substrate 110, a support substrate 140 is disposed above the substrate 110, and the second MEMS oscillator 52 and a circuit section 160 are disposed above the support substrate 140.

The substrate 110 has a base 112, a first primary coating 114, and a second primary coating 116. As the base 112, for example, a semiconductor substrate such as a silicon substrate can be used. As the base 112, various kinds of substrates such as a ceramic substrate, a glass substrate, sapphire substrate, a diamond substrate, and a synthetic resin substrate may be used. The first primary coating 114 is formed on the base 112. The material of the first primary coating 114 is, for example, silicon oxide. The second primary coating 116 is formed on the first primary coating 114. The material of the second primary coating 116 is, for example, silicon nitride.

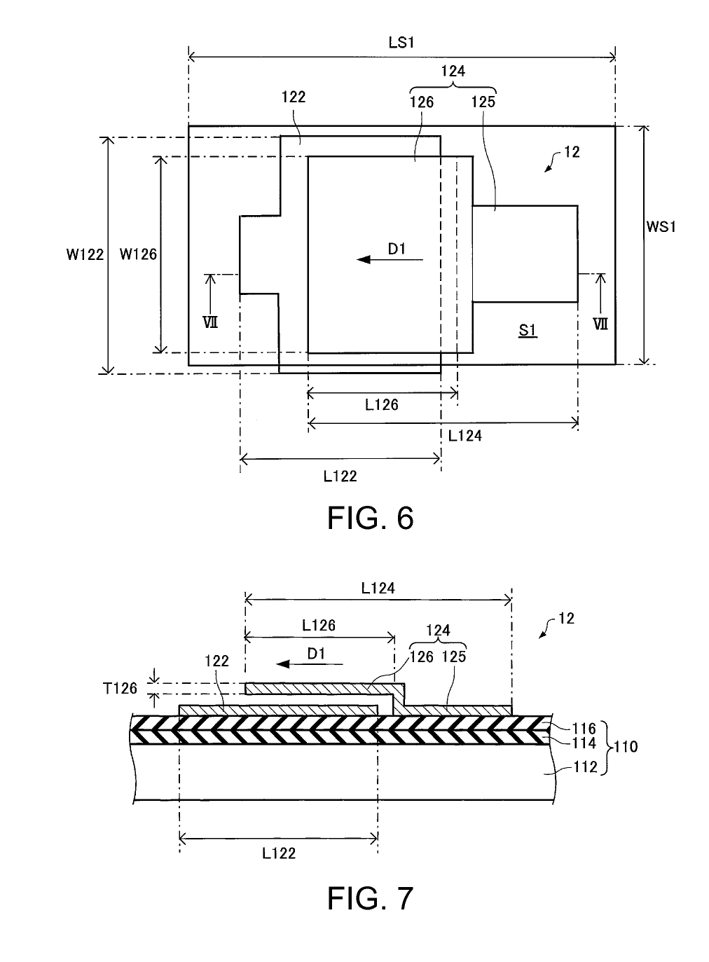

In the example shown in the drawing, the first MEMS oscillator 12 is disposed between the substrate 110 and the support substrate 140. The first MEMS oscillator 12 is formed on the substrate 110. FIG. 6 is a plan view schematically showing the first MEMS oscillator 12. FIG. 7 is a sectional view schematically showing the first MEMS oscillator 12. Incidentally, FIG. 7 is a sectional view taken on the line VII-VII of FIG. 6.

The first MEMS oscillator 12 has a fixed electrode (a first electrode) 122 and a movable electrode (a second electrode) 124.

The fixed electrode 122 is formed on the substrate 110. The fixed electrode 122 is, for example, a layered or thin-film electrode. The length L122 of the fixed electrode 122 is, for example, 30 μm or more but 50 μm or less, and the width W122 of the fixed electrode 122 is about 100 μm, for example.

Here, the length L122 of the fixed electrode 122 refers to the size of the fixed electrode 122 in a direction D1 in which a movable part 126 of the movable electrode 124 extends. Moreover, the width W122 of the fixed electrode 122 refers to the size of the fixed electrode 122 in a direction perpendicular to the direction D1 in a plan view. Incidentally, a case in which something is seen in a plan view refers to a case in which something is seen from the thickness direction of the substrate 110. Moreover, the thickness direction of the substrate 110 refers to the direction of the perpendicular line from a principal surface (a surface on which an element is formed) of the substrate 110. The resonance frequency of the first MEMS oscillator 12 depends on the magnitude (the length L126) of the direction D1 in which the movable part 126 extends.

The movable electrode 124 has a support part 125 formed on the substrate 110 and the movable part 126 that extends from the support part 125 and is disposed so as to face the fixed electrode 122. The support part 125 supports the movable part 126 in such a way that the movable part 126 is disposed so as to face the fixed electrode 122. The movable part 126 is disposed above the fixed electrode 122 so as to leave a predetermined clearance between the movable part 126 and the fixed electrode 122. In the example shown in the drawing, the movable electrode 124 is formed into the shape of a cantilever.

The length L124 of the movable electrode 124 is, for example, 30 μm or more but 50 μm or less. Moreover, the length L126 of the movable part 126 is 20 μm or more but 40 μm or less, and the width W126 of the movable part 126 is about 80 μm, for example. Furthermore, the thickness T126 of the movable part 126 is, for example, 100 nm or more but 200 nm or less.

Here, the length L124 of the movable electrode 124 refers to the size of the movable electrode 124 in the direction D1. Moreover, the length L126 of the movable part 126 refers to the size of the movable part 126 in the direction D1. The width W126 of the movable part 126 refers to the size of the movable part 126 in a direction perpendicular to the direction D1.

When a voltage is applied between the fixed electrode 122 and the movable electrode 124, the movable part 126 can oscillate by an electrostatic force generated between the electrodes 122 and 124. That is, the first MEMS oscillator 12 is an electrostatic MEMS oscillator.

The material of the fixed electrode 122 and the movable electrode 124 is, for example, polycrystalline silicon provided with conductivity as a result of being doped with predetermined impurities.

The first MEMS oscillator 12 is disposed in a space (cavity space) S1 surrounded with the substrate 110, an insulating layer 130, and the support substrate 140. The space S1 may be in a state in which the pressure is reduced, for example. This makes it possible to reduce the air resistance when the movable part 126 is oscillating.

The length LS1 of the space S1 is about 300 μm, for example, and the width WS1 of the space S1 is about 200 μm, for example. Here, the length LS1 of the space S1 refers to the size of the space S1 in the direction D1, and the width WS1 of the space S1 refers to the size of the space S1 in a direction perpendicular to the direction D1 in a plan view.

As shown in FIG. 5, the insulating layer 130 is provided between the substrate 110 and the support substrate 140. The material of the insulating layer 130 is, for example, silicon oxide.

The support substrate 140 is formed on the insulating layer 130. In the example shown in the drawing, the support substrate 140 is disposed above the substrate 110 with the insulating layer 130 sandwiched between the support substrate 140 and the substrate 110. The support substrate 140 has a base 142, a third primary coating 144, and a fourth primary coating 146.

As the base 142, for example, a semiconductor substrate such as a silicon substrate can be used. As the base 142, various kinds of substrates such as a ceramic substrate, a glass substrate, sapphire substrate, a diamond substrate, and a synthetic resin substrate may be used. The third primary coating 144 is formed on the base 142. The material of the third primary coating 144 is, for example, silicon oxide. The fourth primary coating 146 is formed on the third primary coating 144. The material of the fourth primary coating 146 is, for example, silicon nitride. On the support substrate 140, an interlayer insulating layer 148 is formed.

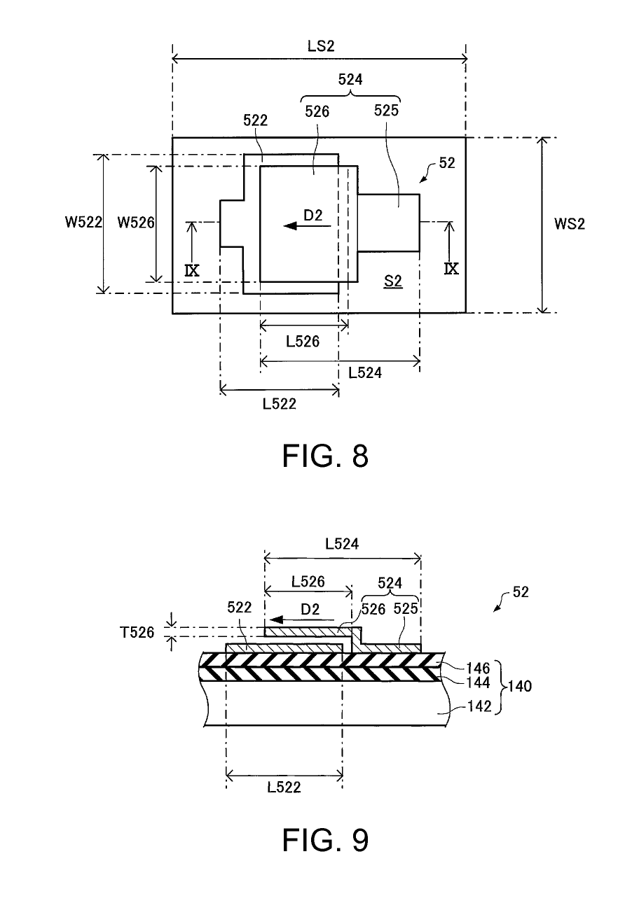

The second MEMS oscillator 52 is formed on the support substrate 140. FIG. 8 is a plan view schematically showing the second MEMS oscillator 52. FIG. 9 is a sectional view schematically showing the second MEMS oscillator 52. Incidentally, FIG. 9 is a sectional view taken on the line IX-IX of FIG. 8.

The second MEMS oscillator 52 has a fixed electrode (a first electrode) 522 and a movable electrode (a second electrode) 524.

The fixed electrode 522 is formed on the support substrate 140. The fixed electrode 522 is, for example, a layered or thin-film electrode. The length L522 of the fixed electrode 522 is, for example, 3 μm or more but 5 μm or less, and the width W522 of the fixed electrode 522 is about 5 μm, for example.

Here, the length L522 of the fixed electrode 522 refers to the size of the fixed electrode 522 in a direction D2 in which a movable part 526 of the movable electrode 524 extends. Moreover, the width W522 of the fixed electrode 522 refers to the size of the fixed electrode 522 in a direction perpendicular to the direction D2 in a plan view. Incidentally, the resonance frequency of the second MEMS oscillator 52 depends on the magnitude (the length L526) of the direction D2 in which the movable part 526 extends.

The movable electrode 524 has a support part 525 formed on the support substrate 140 and the movable part 526 which extends from the support part 525 and is disposed so as to face the fixed electrode 522. The support part 525 supports the movable part 526 in such a way that the movable part 526 is disposed so as to face the fixed electrode 522. The movable part 526 is disposed above the fixed electrode 522 so as to leave a predetermined clearance between the movable part 526 and the fixed electrode 522. In the example shown in the drawing, the movable electrode 524 is formed into the shape of a cantilever.

The length L524 of the movable electrode 524 is, for example, 3 μm or more but 5 μm or less. Moreover, the length L526 of the movable part 526 is 2 μm or more but 4 μm or less, and the width W526 of the movable part 526 is about 4 μm, for example. Furthermore, the thickness T526 of the movable part 526 is about 300 nm, for example.

Here, the length L524 of the movable electrode 524 refers to the size of the movable electrode 524 in the direction D2. Moreover, the length L526 of the movable part 526 refers to the size of the movable part 526 in the direction D2. The width W525 of the movable part 526 refers to the size of the movable part 526 in a direction perpendicular to the direction D2 in a plan view.

When a voltage is applied between the fixed electrode 522 and the movable electrode 524, the movable part 526 can oscillate by an electrostatic force generated between the electrodes 522 and 524. That is, the second MEMS oscillator 52 is an electrostatic MEMS oscillator.

The material of the fixed electrode 522 and the movable electrode 524 is, for example, polycrystalline silicon provided with conductivity as a result of being doped with predetermined impurities.

A covering structure 150 is formed on the support substrate 140. The covering structure 150 may hermetically seal the second MEMS oscillator 52 in a state in which the pressure is reduced. This makes it possible to reduce the air resistance when the movable part 526 is oscillating. The second MEMS oscillator 52 is disposed in a space (cavity space) S2 surrounded with the covering structure 150 and the support substrate 140. The length LS2 (see FIG. 8) of the space S2 is about 15 μm, for example, and the width WS2 of the space S2 is about 12 μm, for example. Here, the length LS2 of the space S2 refers to the size of the space S2 in the direction D2, and the width WS2 of the space S2 refers to the size of the space S2 in a direction perpendicular to the direction D2 in a plan view.

The space S1 surrounding the first MEMS oscillator 12 has a region overlapping with the space S2 surrounding the second MEMS oscillator 52 in a plan view of the substrate 110, for example. That is, a projection region obtained by projecting the space S1 onto the substrate 110 has a region overlapping with a projection region obtained by projecting the space S2 onto the substrate 110. As a result, it is possible to reduce the size of the oscillator in a plan view, that is, achieve miniaturization of a device. In an example shown in FIG. 5, the space S1 overlaps with the space S2 in a plan view of the substrate 110.

In the oscillator 100, in a plan view, the area (L126×W126) of the movable part 126 of the first MEMS oscillator 12 is greater than the area (L526×W526) of the movable part 526 of the second MEMS oscillator 52. As a result, the first MEMS oscillator 12 has a lower loss than the second MEMS oscillator 52 and has a Q value which is higher than that of the second MEMS oscillator 52. Furthermore, the first MEMS oscillator 12 is less affected by a production error than the second MEMS oscillator 52. Therefore, the reference oscillation circuit 10 using the first MEMS oscillator 12 can output a reference signal fᵣₑ having a high degree of frequency accuracy.

Moreover, in other words, in the oscillator 100, in a plan view, the area (L526×W526) of the movable part 526 of the second MEMS oscillator 52 is smaller than the area (L126×W126) of the movable part 126 of the first MEMS oscillator 12. As a result, the second MEMS oscillator 52 has a higher loss than the first MEMS oscillator 12 and has a Q value which is lower than that of the first MEMS oscillator 12. Therefore, the voltage-controlled oscillation circuit 50 using the second MEMS oscillator 52 can increase the variable width of the oscillation frequency.

The circuit section 160 is formed on the support substrate 140. The circuit section 160 has a circuit for operating the oscillator 100 other than the MEMS oscillators 12 and 52. Specifically, the circuit section 160 has, for example, the phase-comparison circuit 20, the charge pump circuit 30, the loop filter 40, and the frequency division circuit 60 which are shown in FIG. 1. Furthermore, the circuit section 160 has, for example, the inverting amplifier circuit 14 forming the reference oscillation circuit 10 shown in the FIG. 2 and the inverting amplifier circuit 54, the variable-capacitance diodes 59a and 59b, etc. which form the voltage-controlled oscillation circuit 50 shown in FIG. 4. That is, in the oscillator 100, the reference oscillation circuit 10, the phase-comparison circuit 20, the charge pump circuit 30, the loop filter 40, the voltage-controlled oscillation circuit 50, and the frequency division circuit 60 are formed above the substrate 110. The circuit section 160 includes, for example, transistors 162, wiring lines 164, etc. The first MEMS oscillator 12 and the circuit section 160 are electrically connected via a connecting member 170 such as a bonding wire. In the example shown in the drawing, the first MEMS oscillator 12 is electrically connected to a pad 172 formed on the substrate 110, and the pad 172 and the connecting member 170 are electrically connected. In addition, the connecting member 170 and the wiring lines 164 of the circuit section 160 are electrically connected. Moreover, the second MEMS oscillator 52 and the circuit section 160 are electrically connected by wiring lines (not shown) formed in the interlayer insulating layer 148.

A sealing section 180 seals the substrate 110, the first MEMS oscillator 12, the support substrate 140, the second MEMS oscillator 52, and the circuit section 160. As a result, it is possible to protect these component elements 110, 12, 140, 52, and 160 from an external shock, humidity, heat, and the like. The material of the sealing section 180 is, for example, epoxy resin.

Terminals 190 are connected to the circuit section 160 via a connecting member (not shown). The terminals 190 function as an input terminal and an output terminal of the oscillator 100. The material of the terminals 190 is, for example, a conductive metal.

### 1.2 Method for Producing the Oscillator According to the First Embodiment

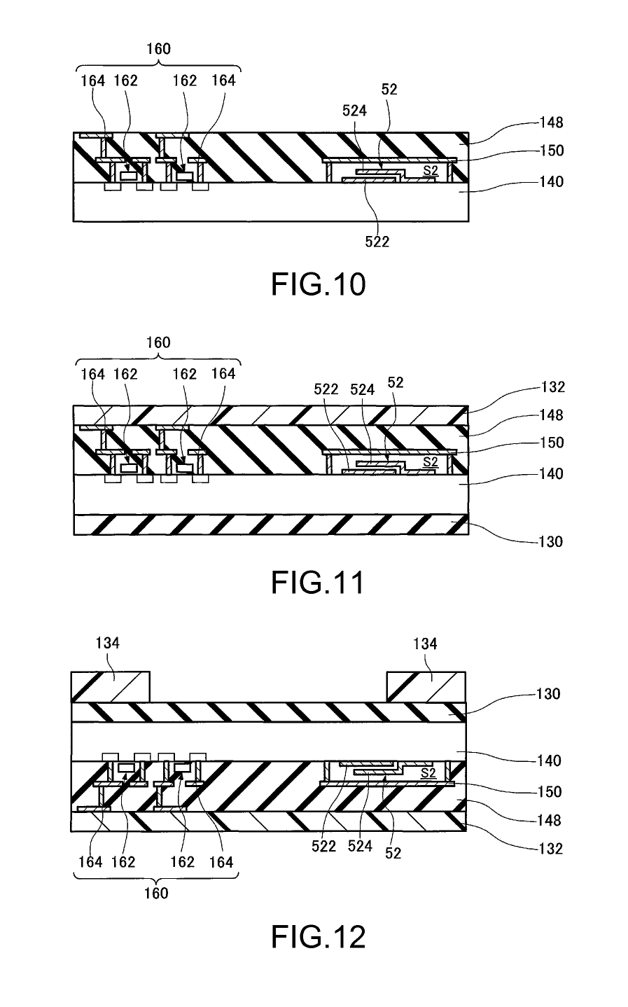

Next, a method for producing the oscillator 100 according to the first embodiment will be described with reference to the drawings. FIGS. 10 to 15 are sectional views each schematically showing a production process of the oscillator 100.

As shown in FIG. 10, the second MEMS oscillator 52, the circuit section 160, and the covering structure 150 are formed on the support substrate 140. Specifically, the fixed electrode 522 is first formed on the support substrate 110, a sacrifice layer (not shown) covering the fixed electrode 522 is then formed by thermal oxidation, and the movable electrode 524 is formed on the sacrifice layer and the support substrate 140. The fixed electrode 522 and the movable electrode 524 are formed, for example, by film formation performed by CVD or sputtering and patterning performed by photolithography. Next, the interlayer insulating layer 148 and the covering structure 150 are formed, and the sacrifice layer is removed by supplying an etchant to the sacrifice layer through a through hole (not shown) formed in the covering structure 150. The covering structure 150 is formed, for example, by combining film formation performed by CVD or the like and patterning performed by photolithography. The second MEMS oscillator 52 and the covering structure 150 are formed by the processes described above. Moreover, the circuit section 160 is formed, for example, in a process that is identical with or similar to the process for forming the second MEMS oscillator 52.

As shown in FIG. 11, a protective film 132 is formed on the interlayer insulating layer 148. The material of the protective film 132 is, for example, polyimide resin or a resist. Next, the insulating layer 130 is formed on a back surface (a surface opposite to the principal surface) of the support substrate 140. The insulating layer 130 is formed by CVD, for example.

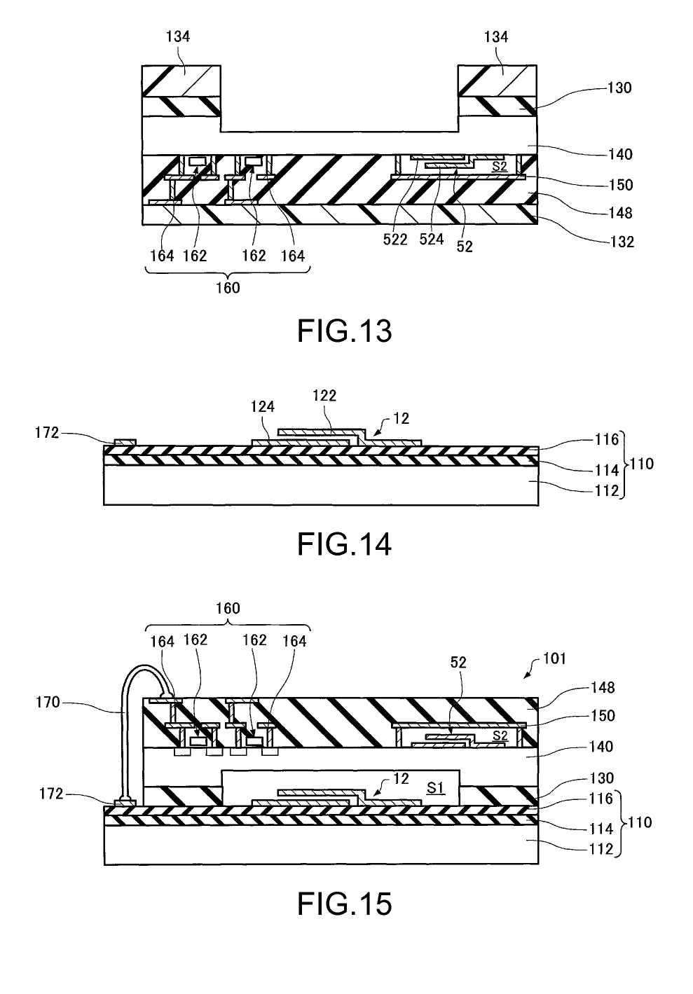

As shown in FIG. 12, a resist 134 is formed on the insulating layer 130. The resist 134 is formed into a predetermined shape by exposure and development. Incidentally, in FIGS. 12 and 13, for the sake of convenience, the structure shown in FIG. 11 is turned upside down.

As shown in FIG. 13, the insulating layer 130 and the support substrate 140 are etched by using the resist 134 as a mask, whereby a recessed portion is formed. Then, the protective film 132 and the resist 134 are removed.

As shown in FIG. 14, the first MEMS oscillator 12 is formed on the substrate 110. The first MEMS oscillator 12 is formed, for example, in a process similar to the above-described process for forming the second MEMS oscillator 52. Next, the pad 172 is formed on the substrate 110.

As shown in FIG. 15, the insulating layer 130 and the substrate 110 are bonded together. As a result, the substrate 110 and the support substrate 140 are laminated, whereby a laminated body 101 is formed. The insulating layer 130 and the substrate 110 are bonded together in a state in which the pressure is reduced, for example. This makes it possible to bring the space S1 into a state in which the pressure is reduced. The insulating layer 130 and the substrate 110 are bonded together by using an adhesive, for example. Next, the laminated body 101 may be cut to a predetermined size by dicing. Then, the connecting member 170 for electrically connecting the pad 172 and the wiring lines 164 is formed.

As shown in FIG. 5, the terminals 190 and the sealing section 180 are formed. The sealing section 180 is formed by covering the substrate 110, the first MEMS oscillator 12, the support substrate 140, the second MEMS oscillator 52, and the circuit section 160 with resin or the like.

The oscillator 100 can be produced by the processes described above.

The oscillator 100 has the following features, for example.

The oscillator 100 can be provided with the reference oscillation circuit 10 including the first MEMS oscillator 12. This makes it possible to dispose the oscillator forming the reference oscillation circuit 10 on the substrate 110 without externally attaching the oscillator. As a result, it is possible to achieve miniaturization of the device. Furthermore, for example, the oscillator 100 can be formed as one chip.

The oscillator 100 can be provided with the voltage-controlled oscillation circuit 50 including the second MEMS oscillator 52. An oscillation circuit using a MEMS oscillator can make the area thereof in the substrate smaller as compared to, for example, an LC oscillation circuit which is generally used in a voltage-controlled oscillation circuit. As a result, the oscillator 100 can achieve further miniaturization of the device.

Furthermore, the oscillation circuit including the MEMS oscillator can improve the frequency accuracy as compared to the LC oscillation circuit. As a result, with the voltage-controlled oscillation circuit 50 including the second MEMS oscillator 52, it is possible to lower the time constant of the loop filter 40. This makes it possible to reduce in-band noise and thereby improve the oscillation characteristics of the oscillator.

In the oscillator 100, the first MEMS oscillator 12 is disposed between the substrate 110 and the support substrate 140, and the second MEMS oscillator 52 is disposed on the support substrate 140. As described above, since the substrate 110 and the support substrate 140 are laminated in the oscillator 100, it is possible to reduce the size of the oscillator in a plan view. That is, it is possible to achieve miniaturization of the device.

In the oscillator 100, the reference oscillation circuit 10, the voltage-controlled oscillation circuit 50, the frequency division circuit 60, and the phase-comparison circuit 20 are formed above the substrate 110. This makes it possible to achieve miniaturization of the device. Furthermore, for example, the oscillator can be formed as one chip.

### 1.3 Modified Examples of the Oscillator According to the First Embodiment

Next, oscillators according to modified examples of the first embodiment will be described with reference to the drawings. Incidentally, here, only differences from the above-mentioned oscillator 100 are described, and descriptions of portions similar to those of the oscillator 100 will be omitted.

### (1) First Modified Example

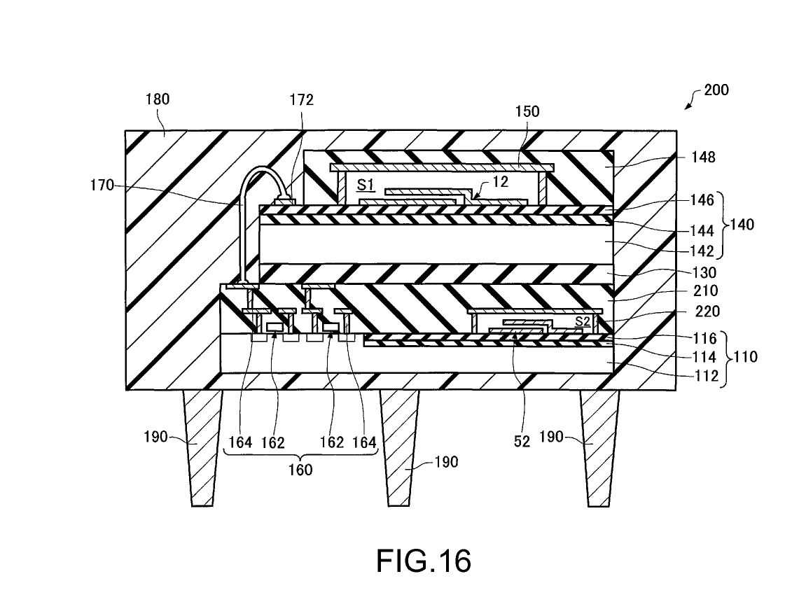

First, a first modified example will be described. FIG. 16 is a sectional view schematically showing an oscillator 200 according to the first modified example. Hereinafter, in the oscillator according to the first modified example, component elements having the functions similar to those of the component elements of the oscillator 100 according to the first embodiment are identified with the same reference numerals, and detailed descriptions thereof will be omitted.

In the oscillator 100, as shown in FIG. 5, the first MEMS oscillator 12 is disposed between the substrate 110 and the support substrate 140, and the second MEMS oscillator 52 is disposed above the support substrate 140. On the other hand, in the oscillator 200, as shown in FIG. 16, the second MEMS oscillator 52 is disposed between the substrate 110 and the support substrate 140, and the first MEMS oscillator 12 is disposed above the support substrate 140. As described above, in the oscillator 200, as is the case with the oscillator 100, since the substrate 110 and the support substrate 140 are laminated, it is possible to reduce the size of the oscillator in a plan view. That is, it is possible to achieve miniaturization of the device.

In the oscillator 200, as shown in FIG. 16, an interlayer insulating layer 210 and a covering structure 220 are formed on the substrate 110. The second MEMS oscillator 52 is disposed in a space S2 surrounded with the covering structure 220 and the substrate 110. The second MEMS oscillator 52 is formed on the substrate 110. The insulating layer 130 is disposed between the interlayer insulating layer 210 and the support substrate 140. Moreover, the first MEMS oscillator 12 is disposed in a space S1 surrounded with the covering structure 150 and the support substrate 140. The first MEMS oscillator 12 is formed on the support substrate 140. Moreover, the circuit section 160 is formed on the substrate 110. That is, the circuit section 160 is disposed between the substrate 110 and the support substrate 140.

### (2) Second Modified Example

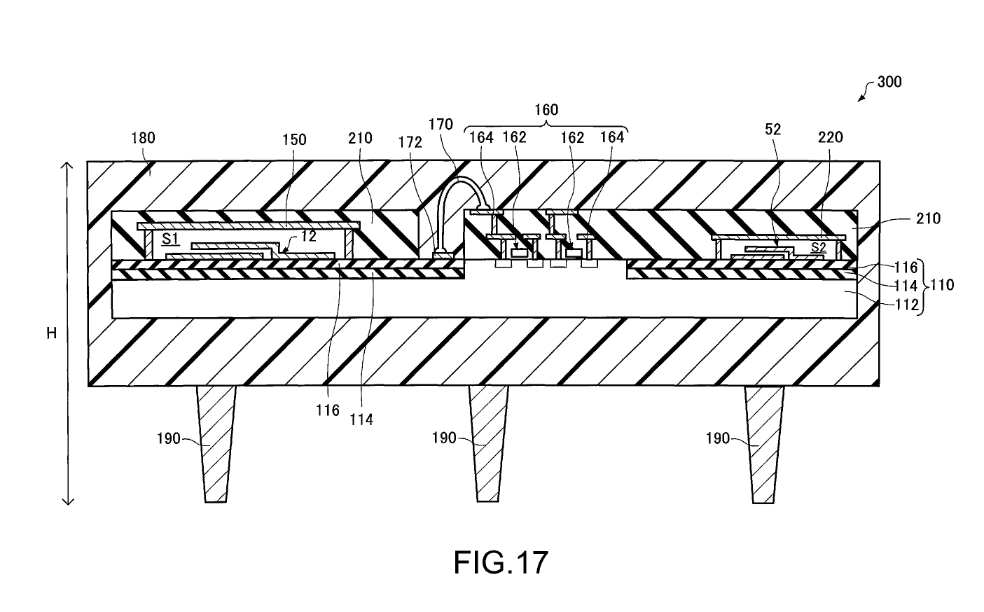

Next, a second modified example will be described. FIG. 17 is a sectional view schematically showing an oscillator 300 according to the second modified example. Hereinafter, in the oscillator according to the second modified example, component elements having the functions similar to those of the component elements of the oscillators 100 and 200 described above are identified with the same reference numerals, and detailed descriptions thereof will be omitted.

As shown in FIG. 5, the oscillator 100 has the substrate 110 and the support substrate 140. On the other hand, as shown in FIG. 17, the oscillator 300 has the substrate 110. That is, the oscillator 300 does not have a support substrate. As a result, the oscillator 300 can reduce the height H as compared to the oscillators 100 and 200. Incidentally, the height H of the oscillator 300 refers to a distance between the tips of the terminals 190 and the top surface of the sealing section 180.

In the oscillator 300, the first MEMS oscillator 12 and the second MEMS oscillator 52 are formed on the substrate 110. The first MEMS oscillator 12 is disposed in a space S1 surrounded with the covering structure 150 formed on the substrate 110 and the substrate 110. Moreover, the second MEMS oscillator 52 is disposed in a space S2 surrounded with the covering structure 220 and the substrate 110. The circuit section 160 is formed on the substrate 110.

The thickness of the movable part 126 of the first MEMS oscillator 12 is 300 nm, for example, and the thickness of the movable part 526 of the second MEMS oscillator 52 is 300 nm, for example. The thickness of the fixed electrode 122 of the first MEMS oscillator 12 and the thickness of the fixed electrode 122 of the second MEMS oscillator 52 are equal to each other, for example. As described above, by making the thicknesses of the corresponding electrodes equal to each other, it is possible to form the first MEMS oscillator 12 and the second MEMS oscillator 52 on the same substrate 110 with ease.

### (3) Third Modified Example

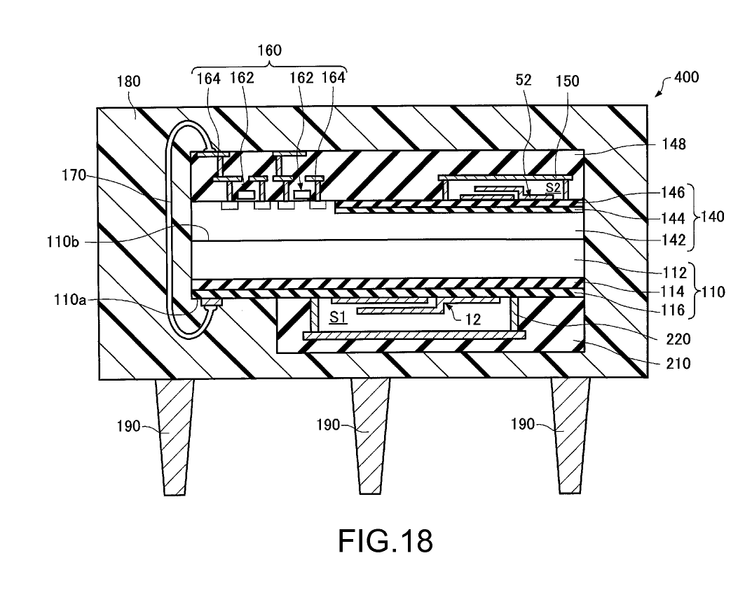

Next, a third modified example will be described. FIG. 18 is a sectional view schematically showing an oscillator 400 according to the third modified example. Hereinafter, in the oscillator according to the third modified example, component elements having the functions similar to those of the component elements of the oscillators 100, 200, and 300 described above are identified with the same reference numerals, and detailed descriptions thereof will be omitted.

In the oscillator 100, as shown in FIG. 5, the first MEMS oscillator 12 is disposed between the substrate 110 and the support substrate 140, and the second MEMS oscillator 52 is disposed above the support substrate 140. On the other hand, in the oscillator 400, as shown in FIG. 18, the first MEMS oscillator 12 is disposed on a side of the substrate 110 where a first surface 110a is located, and the second MEMS oscillator 52 is disposed on a side of the substrate 110 where a second surface 110b is located. As described above, in the oscillator 400, as is the case with the oscillators 100 and 200, since the substrate 110 and the support substrate 140 are laminated, it is possible to reduce the size of the oscillator in a plan view. That is, it is possible to achieve miniaturization of the device.

The substrate 110 has the first surface 110a and the second surface 110b on the side opposite to the first surface 110a. In the example shown in the drawing, the first surface 110a is a lower surface of the substrate 110 and is a surface (a principal surface) on which the first MEMS oscillator 12 is formed. The second surface 110b is a top surface (a back surface) of the substrate 110. The first primary coating 114 and the second primary coating 116 are formed on the side where the first surface 110a is located.

The first MEMS oscillator 12 is formed on the first surface 110a of the substrate 110. Moreover, the second MEMS oscillator 52 and the circuit section 160 are formed on a top surface (a principal surface) of the support substrate 140. In the oscillator 400, the second surface 110b of the substrate 110 and a lower surface (a back surface) of the support substrate 140 are bonded together. The second surface 110b of the substrate 110 and the lower surface of the support substrate 140 are bonded together by using a publicly known adhesive, for example.

### 2. Second Embodiment

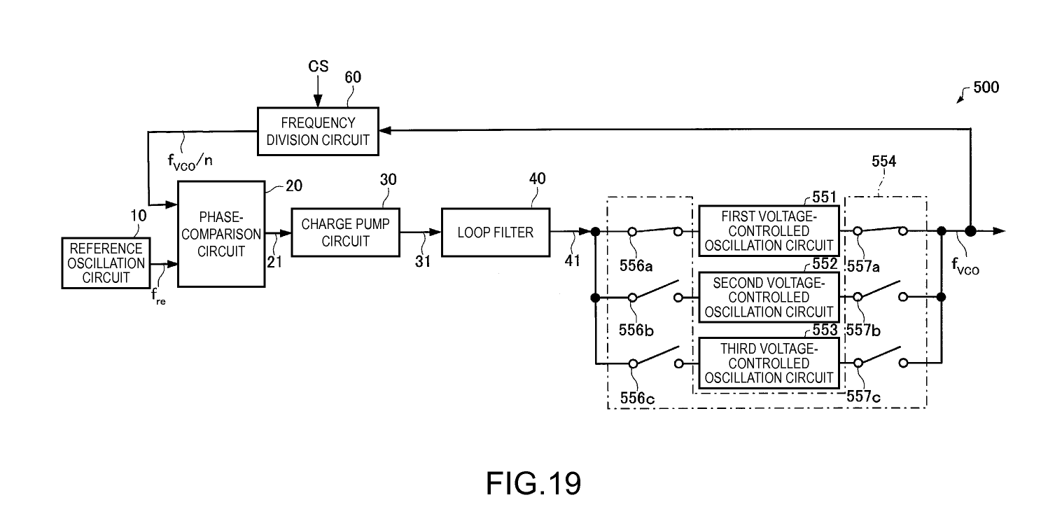

Next, an oscillator according to a second embodiment will be described with reference to the drawings. FIG. 19 is a block diagram showing the configuration of an oscillator 500 according to this embodiment. Hereinafter, in the oscillator according to the second embodiment, component elements having the functions similar to those of the component elements of the oscillators 100, 200, 300, and 400 described above are identified with the same reference numerals, and detailed descriptions thereof will be omitted.

In the oscillator 500, a plurality of voltage-controlled oscillation circuits whose oscillation frequencies are different from one another are provided. The oscillator 500 further includes a selection circuit that selects one of the plurality of voltage-controlled oscillation circuits.

In the example shown in the drawing, the oscillator 500 includes a first voltage-controlled oscillation circuit 551, a second voltage-controlled oscillation circuit 552, a third voltage-controlled oscillation circuit 553, and a selection circuit 554 that selects one of the first to third voltage-controlled oscillation circuits 551, 552, and 553.

The oscillation frequencies of the first to third voltage-controlled oscillation circuits 551, 552, and 553 are different from one another. The selection circuit 554 selects one of the first to third voltage-controlled oscillation circuits 551, 552, and 553. In an example shown in FIG. 19, a state in which the first voltage-controlled oscillation circuit 551 is selected is shown. In this case, the control voltage 41 is input to the first voltage-controlled oscillation circuit 551. In the first voltage-controlled oscillation circuit 551, the oscillation frequency is controlled based on the control voltage 41, and the first voltage-controlled oscillation circuit 551 outputs the oscillation signal f_{VCO}.

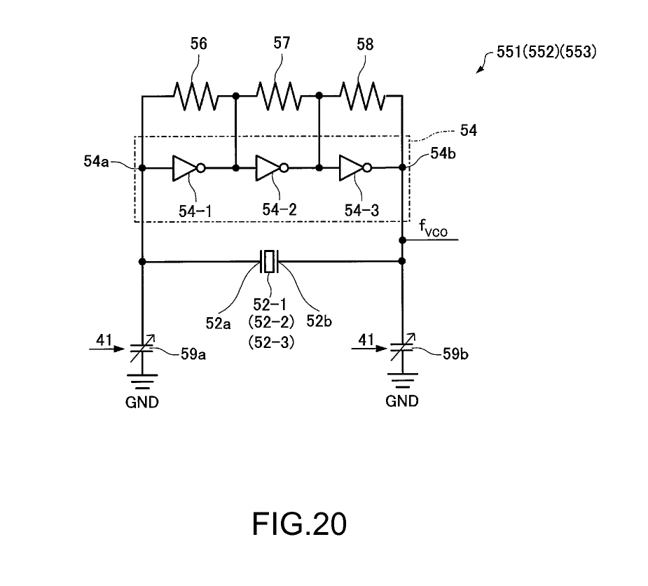

FIG. 20 is a block diagram showing the configuration of the voltage-controlled oscillation circuit 551 (552) (553). Incidentally, in FIG. 20, when an example shown in the drawing is the second voltage-controlled oscillation circuit 552, the second MEMS oscillator is denoted by 52-2; when an example shown in the drawing is the third voltage-controlled oscillation circuit 553, the second MEMS oscillator is denoted by 52-3.

The first voltage-controlled oscillation circuit 551 includes a second MEMS oscillator 52-1. The second voltage-controlled oscillation circuit 552 includes a second MEMS oscillator 52-2. The third voltage-controlled oscillation circuit 553 includes a second MEMS oscillator 52-3. The resonance frequencies of the second MEMS oscillators 52-1, 52-2, and 52-3 are different from one another. As a result, the oscillation frequencies of the first to third voltage-controlled oscillation circuits 551, 552, and 553 are different from one another.

As shown in FIG. 19, the selection circuit 554 can include at least either first switches 556a, 556b, and 556c or second switches 557a, 557b, and 557c, and the first switches 556a, 556b, and 556c switch a connection state between an output terminal of the loop filter 40 and input terminals of the voltage-controlled oscillation circuits 551, 552, and 553 and the second switches 557a, 557b, and 557c switch a connection state between output terminals of the voltage-controlled oscillation circuits 551, 552, and 553 and an input terminal of the frequency division circuit 60 and between the output terminals of the voltage-controlled oscillation circuits 551, 552, and 553 and an output terminal of the oscillator 500. That is, the selection circuit 554 includes the first switches which correspond to the first to third voltage-controlled oscillation circuits 551, 552, and 553 and the second switches which correspond to the first to third voltage-controlled oscillation circuits 551, 552, and 553.

The first switches 556a, 556b, and 556c and the second switches 557a, 557b, and 557c are configured so that the connection state of each switch is switched at least one time or more, and each switch may be formed, for example, as an analog switch whose connection state can be switched more than once or as a fuse or the like whose connection state can be switched only once.

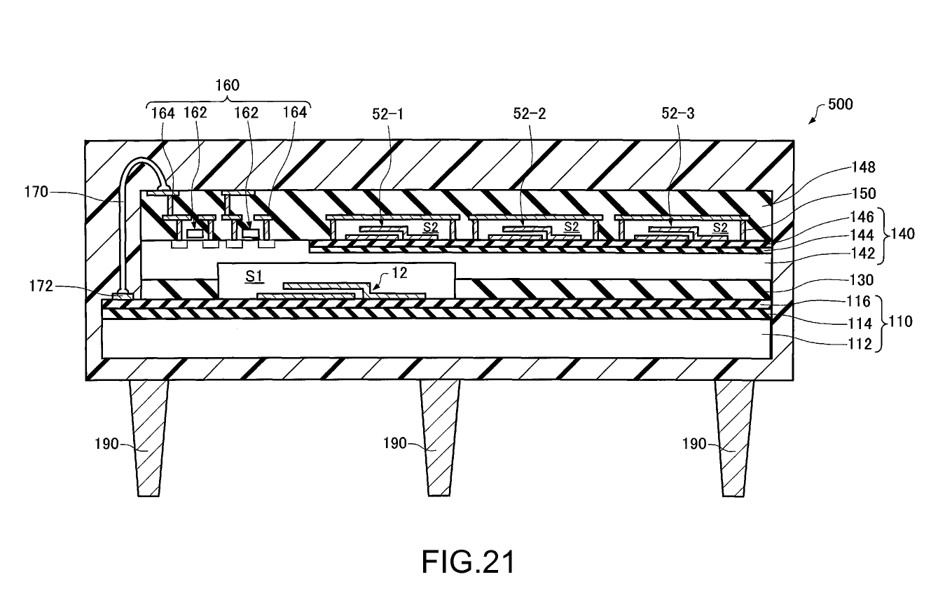

FIG. 21 is a sectional view schematically showing the oscillator 500.

The oscillator 500 includes a plurality of second MEMS oscillators. In the example shown in the drawing, the oscillator 500 includes three second MEMS oscillators 52-1, 52-2, and 52-3. The second MEMS oscillators 52-1, 52-2, and 52-3 are formed on the support substrate 140. The second MEMS oscillators 52-1, 52-2, and 52-3 are disposed in three spaces S2 formed on the support substrate 140. The movable parts of the second MEMS oscillators 52-1, 52-2, and 52-3 have different lengths, for example. This makes it possible to make the resonance frequencies of the second MEMS oscillators 52-1, 52-2, and 52-3 different from one another.

In the oscillator 500, a plurality of voltage-controlled oscillation circuits are provided. The oscillation frequencies of the voltage-controlled oscillation circuits 551, 552, and 553 are different from one another, and the oscillator 500 includes the selection circuit 554 that selects one of the voltage-controlled oscillation circuits 551, 552, and 553. As a result, it is possible to increase the variable width of the frequency of the output signal f_{VCO} of the oscillator 500.

In addition to the effect described above, the oscillator 500 also obtains the effects similar to those of the oscillator 100 according to the first embodiment.

It is to be understood that the above-described embodiments and modified examples are mere examples and the invention is not limited thereto.

For example, in the examples described above, a case in which the movable electrodes of the first MEMS oscillator and the second MEMS oscillator are formed into the shape of a so-called cantilever (in which one support part is provided for the movable part) has been described. However, the movable electrodes of the first MEMS oscillator and the second MEMS oscillator are not limited to this shape and may be formed into the shape of, for example, a beam supported at multiple ends (for example, the shape of a clamped-clamped beam), the shape in which a plurality of support parts are provided for the movable part.

Moreover, for example, two or more embodiments and modified examples can be combined appropriately.

The invention includes a configuration which is substantially identical to the configuration described in the embodiment (for example, a configuration having the same function, method, and result as those of the configuration described in the embodiment or a configuration having the same objective and effects as those of the configuration described in the embodiment). Moreover, the invention includes a configuration in which a nonessential portion of the configuration described in the embodiment is replaced with another portion. Furthermore, the invention includes a configuration that can obtain the same effects as those of the configuration described in the embodiment or achieve the same objective as that of the configuration described in the embodiment. In addition, the invention includes a configuration which is obtained by adding a publicly-known technique to the configuration described in the embodiment.

The entire disclosure of Japanese Patent application No. 2011-083353, filed Apr. 5, 2011 is expressly incorporated by reference herein.

What is claimed is:

1. An oscillator comprising:
a substrate;
a reference oscillation circuit including a first MEMS oscillator disposed above the substrate, the reference oscillation circuit outputting a first oscillation signal;
at least one voltage-controlled oscillation circuit including a second MEMS oscillator disposed above the substrate, the oscillation frequency of the at least one voltage-controlled oscillation circuit being controlled based on a control signal, the at least one voltage-controlled oscillation circuit outputting a second oscillation signal;
a frequency division circuit dividing the frequency of the second oscillation signal and outputting a frequency division signal; and
a phase-comparison circuit outputting the control signal based on a phase difference between the frequency division signal and the first oscillation signal,
wherein
the first MEMS oscillator and the second MEMS oscillator each have a first electrode and a second electrode,
the second electrode has a movable part disposed so as to face the first electrode, and
the area of the movable part of the first MEMS oscillator is greater than the area of the movable part of the second MEMS oscillator in a plan view of the substrate.

2. The oscillator according to claim 1 further comprising a support substrate disposed above the substrate, wherein
one of the first MEMS oscillator and the second MEMS oscillator is disposed between the substrate and the support substrate, and
the other of the first MEMS oscillator and the second MEMS oscillator is disposed above the support substrate.

3. The oscillator according to claim 2, wherein
a cavity space surrounding the first MEMS oscillator has a region overlapping with a cavity space surrounding the second MEMS oscillator in a plan view of the substrate.

4. The oscillator according to claim 1, wherein
the reference oscillation circuit, the at least one voltage-controlled oscillation circuit, the frequency division circuit, and the phase-comparison circuit are disposed above the substrate.

5. The oscillator according to claim 1, wherein
the at least one voltage-controlled oscillation circuit includes a plurality of voltage-controlled oscillation circuits,
the oscillation frequencies of the plurality of voltage-controlled oscillation circuits are different from one another, and
the oscillator further includes a selection circuit selecting one of the plurality of voltage-controlled oscillation circuits.

6. The oscillator according to claim 5, wherein
the plurality of voltage-controlled oscillation circuits have second MEMS oscillators, the resonance frequencies of the second MEMS oscillators being different from one another.

7. An oscillator comprising:
a substrate having a first surface and a second surface on a side opposite to the first surface;
a reference oscillation circuit including a first MEMS oscillator disposed on a side where the first surface is located, the reference oscillation circuit outputting a first oscillation signal;
a voltage-controlled oscillation circuit including a second MEMS oscillator disposed on a side where the second surface is located, the oscillation frequency of voltage-controlled oscillation circuit being controlled based on a control signal, the voltage-controlled oscillation circuit outputting a second oscillation signal;
a frequency division circuit dividing the frequency of the second oscillation signal and outputting a frequency division signal; and
a phase-comparison circuit outputting the control signal based on a phase difference between the frequency division signal and the first oscillation signal,
wherein
the first MEMS oscillator and the second MEMS oscillator each have a first electrode and a second electrode,
the second electrode has a movable part disposed so as to face the first electrode, and
the area of the movable part of the first MEMS oscillator is greater than the area of the movable part of the second MEMS oscillator in a plan view of the substrate.
